(19) United States
(12) Patent Application Publication
(10) Pub. No.: US 2026/0323823 A1
(43) Pub. Date: Oct. 15, 2026

(54) PRINTED CIRCUIT BOARD AND ELECTRONIC DEVICE INCLUDING SAME

(71) Applicant: LG INNOTEK CO., LTD., Seoul (KR)

(72) Inventor: Woo Ho JEONG, Seoul (KR)

(21) Appl. No.: 19/475,174

(22) PCT Filed: Mar. 18, 2024
(86) PCT No.: PCT/KR2024/003374

§ 371 Date: Oct. 14, 2025

(30) Foreign Application Priority Data
Apr. 17, 2023 (KR) 10-2023-0050382

(51) Int. Cl. H05K 1/09

(52) U.S. Cl. CPC H05K 1/09; H05K 2201/0355; H05K 2201/2081

(57) ABSTRACT

This printed circuit board may include: a base; a copper foil formed on the base; a solder resist covering the surface of the copper foil; and a fence line arranged along the solder resist, wherein at least a portion of the fence line overlaps the copper foil in the vertical direction.

### TECHNICAL FIELDS

The teachings in accordance with exemplary and non-limiting embodiments of the present invention relate generally to a printed circuit board and an electronic device including the same.

### BACKGROUND ARTS

Within household electronic appliances such as televisions, numerous electronic components are arranged. For example, said electronic components may include printed circuit boards. The printed circuit boards are disposed within a housing that forms the exterior of the electronic device.

At least one or more devices are disposed or mounted upon the printed circuit board. The devices are soldered onto the printed circuit board for electrical connection. Specifically, the printed circuit board comprises a base substrate, a copper foil of metallic material disposed upon the base substrate, and a solder resist disposed upon the surface of the copper foil. The solder resist is applied to the surface of the base substrate, serving to protect the substrate surface, prevent oxidation of surface circuits, and prevent solder from adhering to areas other than the component placement areas.

However, during the application of the solder resist, the outer peripheral area may not be uniformly coated. In such cases, this may become a cause of reduced reliability due to electromigration.

### SUMMARY OF THE INVENTION

### Technical Subject

The present embodiment is intended to provide a printed circuit board module and an electronic device including the same, which can immediately distinguish between coated and uncoated areas and prevent the coating solution from encroaching onto the uncoated areas.

### Technical Solution

A printed circuit board according to an exemplary embodiment of the present invention may comprise: a base; a copper foil formed on the base; a solder resist covering the surface of the copper foil; and a fence line arranged along the solder resist, wherein at least a portion of the fence line overlaps the copper foil in the vertical direction.

Preferably but not necessarily, the fence line may include a first region overlapping the copper foil in the vertical direction and a second region disposed outside the first region and not overlapping the copper foil in the vertical direction.

Preferably but not necessarily, the length of the first region and the length of the second region may be identical when measured in a second direction perpendicular to the vertical direction.

Preferably but not necessarily, based on the second direction perpendicular to the vertical direction, the length of the fence line may be 0.8 mm to 1.2 mm.

Preferably but not necessarily, based on the vertical direction, the length of the second region may be greater than the length of the first region.

Preferably but not necessarily, the fence line may have a closed-loop cross-sectional shape.

Preferably but not necessarily, the surface of the fence line may be disposed with a staircase difference in the vertical direction relative to the surface of the solder resist.

Preferably but not necessarily, the material of the fence line may be silk.

An electronic device according to an exemplary embodiment of the present invention may comprise: a housing; and a printed circuit board disposed within the housing, wherein the printed circuit board may comprise: a base; a copper foil formed on the base; a solder resist covering the surface of the copper foil; and a fence line disposed along the edge of the solder resist, and wherein the fence line is disposed such that at least a portion overlaps the copper foil in the vertical direction.

Preferably but not necessarily, the printed circuit board may include a first region forming a voltage of a first magnitude and a second region forming a voltage of a second magnitude smaller than the first magnitude, the second region being disposed beneath the first region, and the fence line may be disposed along the edge of the solder resist provided on the second region.

### Advantageous Effects

The present embodiment offers the advantage of reinforcing the thickness of the solder resist's edge region via the fence line, thereby preventing moisture penetration through the copper foil.

Furthermore, it offers the advantage of preventing external impacts and damage from being transmitted to the electrical connection region via the fence line.

### BRIEF DESCRIPTIONS OF DRAWINGS

FIG. 1 is a plan view illustrating the surface of a printed circuit board according to an exemplary embodiment of the present invention.

FIG. 2 is a diagram for explaining the manufacturing process of the printed circuit board according to an exemplary embodiment of the present invention.

FIG. 3 is a cross-sectional view of the printed circuit board according to an exemplary embodiment of the present invention.

FIG. 4 is a plan view illustrating the upper surface of the printed circuit board in the copper foil formation area according to an exemplary embodiment of the present invention.

FIG. 5 is an enlarged view of a portion of the surface of a printed circuit board according to the prior art.

FIG. 6 is an enlarged view of a portion of the surface of a printed circuit board according to an exemplary embodiment of the present invention.

### BEST MODES

Hereinafter, the attached drawings are referred to in detail to explain the preferred embodiment of the present invention.

However, the technical idea of the present invention is not limited to the some embodiments described, but can be implemented in various different forms, and within the scope of the technical idea of the present invention, one or more of the components between the embodiments can be selectively combined or replaced.

In addition, the terms used in the embodiments of the present invention (including technical and scientific terms) can be interpreted to mean what a person with ordinary skill in the art would understand, unless explicitly defined and described, and generally understood by a person with ordinary skill in the art. Generally used terms, such as those defined in dictionaries, can be interpreted in the context of the relevant technology.

In addition, the terms used in the embodiments of the present invention are intended to explain the embodiments and are not intended to limit the invention. In this specification, the singular form may include the plural form unless otherwise specified in the text, and when described as ‘A and (and/and) B, C, at least one (or more than one) of A, B, and C,’ it may include one or more of all combinations of A, B, and C.

In addition, terms such as 1, 2, A, B, (a), and (b) may be used to describe the components of the embodiments of the present invention.

Such terms are intended only to distinguish the component from other components and are not limited by the nature, order, or sequence of the component.

And, if any component is described as being ‘connected’, ‘coupled’ or ‘attached’ to another component, that component may be directly connected, coupled or attached to that other component, as well as being ‘connected’, ‘coupled’ or ‘attached’ to another component that is between that component and that other component.

In addition, when it is stated that each component is formed or arranged ‘above or below’, the above or below includes not only the case where two components are directly in contact with each other, but also the case where one or more other components are formed or arranged between the two components. In addition, when it is expressed as ‘upper or lower’, it can include the meaning of the lower direction as well as the upper direction based on one component.

The printed circuit board according to an embodiment of the present invention may be disposed within a housing (not shown) forming the exterior of an electronic device.

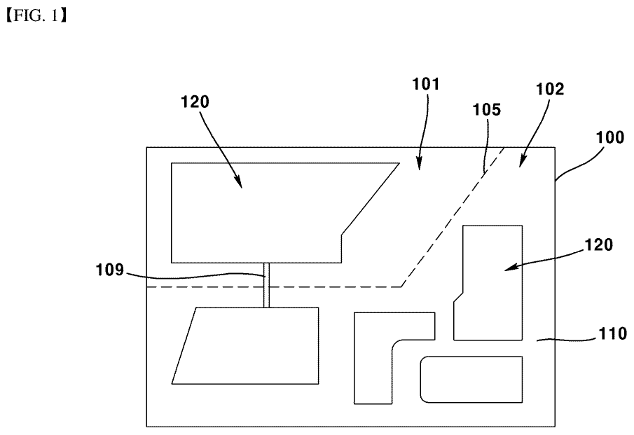

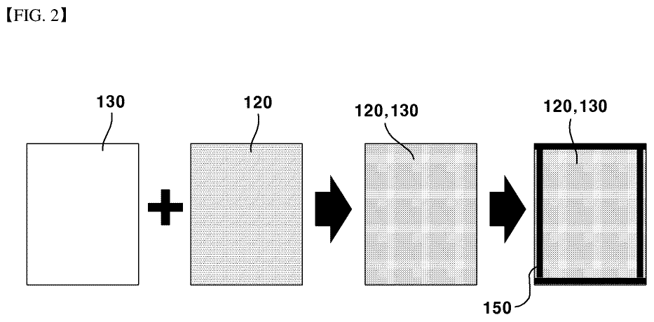

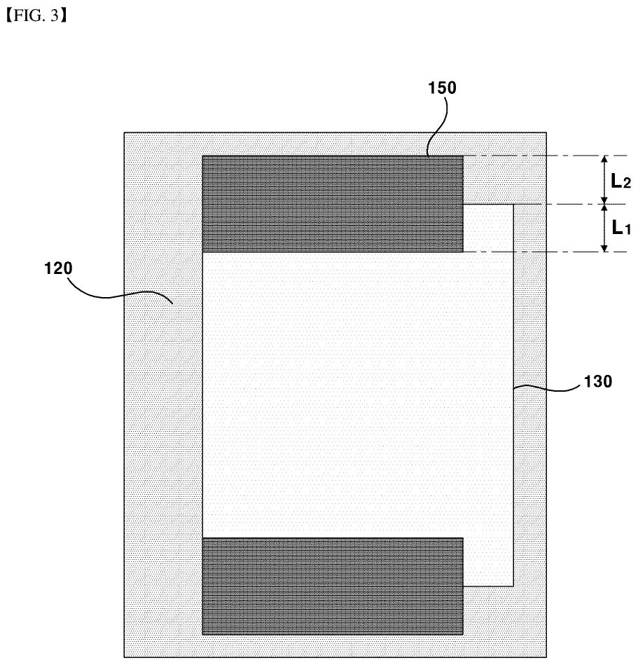

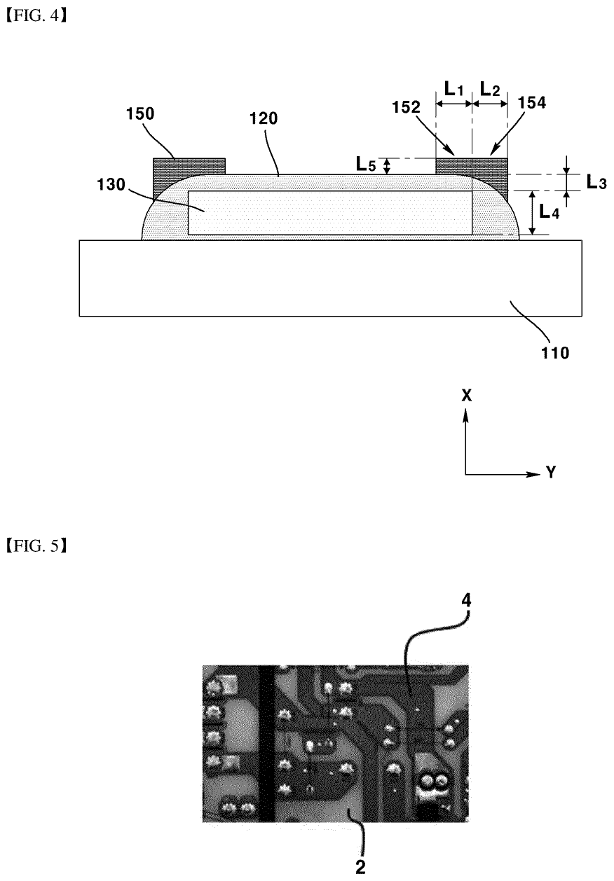

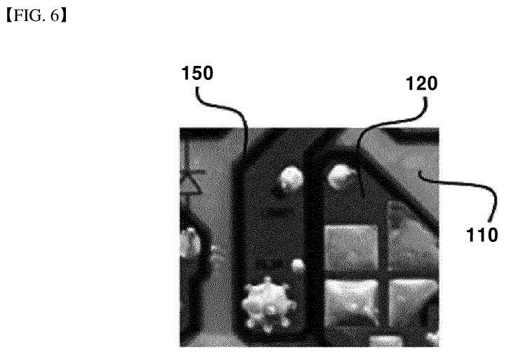

FIG. 1 is a plan view illustrating the surface of a printed circuit board according to an exemplary embodiment of the present invention, FIG. 2 is a diagram for explaining the manufacturing process of the printed circuit board according to an exemplary embodiment of the present invention, FIG. 3 is a cross-sectional view of the printed circuit board according to an exemplary embodiment of the present invention, FIG. 4 is a plan view illustrating the upper surface of the printed circuit board in the copper foil formation area according to an exemplary embodiment of the present invention, FIG. 5 is an enlarged view of a portion of the surface of a printed circuit board according to the prior art, and FIG. 6 is an enlarged view of a portion of the surface of a printed circuit board according to an exemplary embodiment of the present invention.

Referring to FIG. 1, a printed circuit board (100) according to an embodiment of the present invention may be partitioned into a plurality of regions. For example, the plurality of regions may include a first region (101) and a second region (102). The first region (101) and the second region (102) may be disposed vertically adjacent to each other on a base substrate (110). The first region (101) may be dispose above the second region (102). The second region (102) may be disposed below the first region (101). The first region (101) and the second region (102) may be mutually partitioned by a partition line (105). The partition line (105) may comprise ink or silk applied onto the base substrate (110).

Circuit patterns within the first region (101) and circuit patterns within the second region (102) may be electrically interconnected via a connection part (109). The connection part (109) may be disposed to pass through the partition line (105).

The second region (102) may have a higher voltage formed than the first region (101). For example, the first region (101) may have a DC voltage of 200V or less formed, while the second region (102) may have an AC voltage of 400V or more formed. Consequently, when moisture penetrates the second region (102) disposed relatively lower, electrical and circuitry issues may arise.

The following describes a structure to prevent moisture penetration within the second region (102).

Referring to FIGS. 2 to 4 and FIG. 6, the printed circuit board (100) may comprise a base substrate (110), a copper foil (130), a solder resist (120), and fence lines (150).

The base substrate (110) may form the base layer of the printed circuit board (100). The base substrate (110) may be referred to as the base. The base substrate (110) may comprise a plurality of unit substrates. The plurality of unit substrates may be stacked in a vertical direction. For example, the plurality of unit substrates may comprise six units, which may be stacked in a vertical direction.

A copper foil (130) may be formed on the base substrate (110). The copper foil (130) may be referred to as a circuit pattern. The copper foil (130) may be referred to as a lead. The copper foil (130) may be referred to as an electrode line. The copper foil (130) may be of a metallic material. For example, the material of the copper foil (130) may be copper (Cu). Devices may be electrically bonded onto the base substrate (110) via the copper foil (130). The copper foil (130) may be bonded to the surface of the base substrate (110) via tape (not shown) or an adhesive. The thickness of the copper foil (130) may be approximately 30 μm to 40 μm. For example, the thickness (L4, see FIG. 4) of the copper foil (130) may be 35 μm.

The solder resist (120) may be applied to the surface of the base substrate (110), protecting the surface of the base substrate (110), preventing oxidation of the surface circuitry, and preventing solder from adhering to areas other than the component mounting area.

As illustrated in FIG. 4, the solder resist (120) may be disposed to envelop the outer surface of the copper foil (130). Specifically, when the copper foil (130) includes a lower surface bonded to the base substrate (110), an upper surface facing the lower surface, and side surfaces connecting the lower and upper surfaces, the solder resist (120) may be disposed to cover the upper surface and side surfaces of the copper foil (130). The thickness of the solder resist (120), defined from the upper surface of the copper foil (130) to the upper surface of the solder resist (120), may be approximately 5 μm to 15 μm. For example, the thickness (L3, see FIG. 4) of the solder resist (120) may be 10 μm.

The fence line (150) may be disposed along the edge of the solder resist (120). The fence line (150) may form the perimeter of the solder resist (120). The fence line (150) may have a closed-loop configuration in cross-section. The fence line (150) may have a shape that encloses the formation area of the solder resist (120) on the base substrate (110), thereby separating the formation area of the solder resist (120) from the remaining area where the solder resist (120) is not formed. The fence line (150) may be formed from a black silk material.

The fence line (150) may have a shape protruding from the surface of the solder resist (120). The surface of the fence line (150) may be disposed with a staircase difference in the vertical direction relative to the surface of the solder resist (120). Relative to the surface of the base substrate (110), the upper surface of the fence line (150) may be disposed above the upper surface of the solder resist (120). The vertical length from the upper surface of the solder resist (120), which overlaps the upper surface of the copper foil (130) in the vertical direction, to the upper surface of the fence line (150) may be 6 μm to 10 μm. For example, the vertical length (L5) from the upper surface of the solder resist (120) to the upper surface of the fence line (150) may be 8 μm.

The fence line (150) may comprise a first region (152) overlapping the copper foil (130) in the vertical direction, and a second region (154) disposed outside the first region (152) and not overlapping the copper foil (130) in the vertical direction. The first region (152) and the second region (154) may be disposed adjacent to each other in a horizontal direction perpendicular to the vertical direction. When the vertical direction where the base substrate (110), the copper foil (130) and the solder resist (120) are arranged is referred to as the first direction (X, see FIG. 4), the first region (152) and the second region (154) may be disposed in a second direction (Y) perpendicular to the first direction (X).

The first region (152) and the second region (154) may be formed integrally.

With respect to the second direction (Y), the length (L1) of the first region (152) may correspond to the length (L2) of the second region (154). The length (L1) of the first region (152) may be identical to the length (L2) of the second region (154). For example, the length (L1) of the first region (152) and the length (L2) of the second region (154) may each be 0.5 mm. Accordingly, the length (L1+L2) of the fence line (150) relative to the second direction (Y) may be 0.8 mm to 1.2 mm. For example, the length (L1+L2) of the fence line (150) relative to the second direction (Y) may be 1 mm. Consequently, sufficient component placement space within the base substrate (110) can be secured whilst simultaneously preventing moisture penetration into the copper foil (130) placement area efficiently.

With respect to the first direction (X), the length of the second region (154) may be greater than the length of the first region (152). At least a portion of the second region (154) may be disposed to overlap with the copper foil (130) in the second direction (Y).

As illustrated in FIG. 5, printed circuit boards according to prior art lack a partition structure between the solder resist (4) formation area and other areas on the base substrate (2), leaving potential for moisture ingress into the electrical connection area.

However, according to the present embodiment, as shown in FIG. 6, the thickness of the edge region of the solder resist (120) is reinforced via the fence line (150), offering the advantage of preventing moisture from penetrating the copper foil.

Furthermore, the fence line offers the advantage of preventing external impact and damage from being transmitted to the electrical connection region.

Meanwhile, in this embodiment, the moisture penetration prevention structure via the fence line has been described by way of example as being implemented only in the second region of the printed circuit board, which forms a relatively high voltage. However, this is not limiting, and the moisture penetration prevention structure via the fence line may also be implemented in the first region of the printed circuit board.

The foregoing description of the components constituting the embodiments of the present invention as being combined or operating in combination does not imply that the invention is necessarily limited to these embodiments. That is to say, within the scope of the objectives of the present invention, all components may be selectively combined and operated in one or more ways. Furthermore, terms such as “include”, “comprise”, or “have” as described above, unless specifically stated otherwise, imply that the component may be present. Therefore, they should be interpreted as allowing for the inclusion of other components rather than excluding them. All terms, including technical or scientific terms, unless otherwise defined, have the same meaning as generally understood by a person skilled in the art to which the invention pertains. Commonly used terms, such as those defined in dictionaries, should be interpreted in accordance with their meaning within the context of the relevant technology and, unless explicitly defined herein, should not be interpreted in an idealized or overly formalistic sense.

The foregoing description merely exemplifies the technical concept of the present invention. Those skilled in the art to which the present invention pertains will appreciate that various modifications and variations may be made without departing from the essential character of the invention. Therefore, the embodiments disclosed herein are intended to illustrate the technical concept of the invention, not to limit it, and the scope of the technical concept of the invention is not restricted by these embodiments. The scope of protection of the invention shall be interpreted by the appended claims, and all technical concepts within the scope equivalent thereto shall be interpreted as falling within the scope of the invention.

1. A printed circuit board, comprising: a base; a copper foil formed on the base; a solder resist covering a surface of the copper foil; and a fence line arranged along the solder resist, wherein at least a portion of the fence line overlaps the copper foil in a vertical direction.

2. The printed circuit board of claim 1, wherein the fence line includes a first region overlapping the copper foil in the vertical direction and a second region disposed outside the first region and not overlapping the copper foil in the vertical direction.

3. The printed circuit board of claim 2, wherein a length of the first region and a length of the second region are identical when measured in a second direction perpendicular to the vertical direction.

4. The printed circuit board of claim 2, wherein a length of the fence line is 0.8 mm to 1.2 mm, based on a second direction perpendicular to the vertical direction.

5. The printed circuit board of claim 2, wherein a length of the second region is greater than a length of the first region, based on the vertical direction.

6. The printed circuit board of claim 1, wherein the fence line has a closed-loop cross-sectional shape.

7. The printed circuit board of claim 1, wherein a surface of the fence line is disposed with a staircase difference in the vertical direction relative to a surface of the solder resist.

8. The printed circuit board of claim 1, wherein a material of the fence line is silk.

9. The printed circuit board of claim 1, wherein a thickness of the copper foil is greater than a thickness of the solder resist.

10. The printed circuit board of claim 1, wherein a thickness of the solder resist is greater than a thickness of the fence line.

11. An electronic device, comprising: a housing; and a printed circuit board disposed within the housing, wherein the printed circuit board comprises: a base; a copper foil formed on the base; a solder resist covering a surface of the copper foil; and a fence line disposed along an edge of the solder resist, and wherein the fence line is disposed such that at least a portion overlaps the copper foil in a vertical direction.

12. The electronic device of claim 9, wherein the printed circuit board includes a first region forming a voltage of a first magnitude and a second region forming a voltage of a second magnitude smaller than the first magnitude, the second region is disposed under the first region, and the fence line is disposed along the edge of the solder resist provided on the second region.

13. The electronic device of claim 11, wherein the fence line includes a first region overlapping the copper foil in the vertical direction and a second region disposed outside the first region and not overlapping the copper foil in the vertical direction.

14. The electronic device of claim 13, wherein a length of the first region and a length of the second region are identical when measured in a second direction perpendicular to the vertical direction.

15. The electronic device of claim 13, wherein a length of the fence line is 0.8 mm to 1.2 mm, based on a second direction perpendicular to the vertical direction.

16. The electronic device of claim 13, wherein a length of the second region is greater than a length of the first region, based on the vertical direction.

17. The electronic device of claim 11, wherein the fence line has a closed-loop cross-sectional shape.

18. The electronic device of claim 11, wherein a surface of the fence line is disposed with a staircase difference in the vertical direction relative to a surface of the solder resist.

19. The electronic device of claim 11, wherein a thickness of the copper foil is greater than a thickness of the solder resist.

20. The electronic device of claim 11, wherein a thickness of the solder resist is greater than a thickness of the fence line.
